(19) United States
(12) Patent Application Publication
(10) Pub. No.: US 2006/0095222 A1
(43) Pub. Date: May 4, 2006

(54) Optic module calibration

(75) Inventors: Maurice M. Reintjes, Beaverton, OR (US); Charles E. Chang, Coto de Caza, CA (US); Emil Y. Chao, Laguna Hills, CA (US)

Correspondence Address: FARJAMI & FARJAMI LLP, Suite 360, 26522 La Alameda Avenue, Mission Viejo, CA, 92691, US

(73) Assignee: Mindspeed Technologies, Inc.

(21) Appl. No.: 10/981,027

(22) Filed: Nov. 4, 2004

(51) Int. Cl. G01R 35/00

(52) U.S. Cl. 702/106

(57) ABSTRACT

A system is provided for calibrating a production module having a production module transmitter and a production module receiver. A calibrated reference module includes a calibrated reference module transmitter and a calibrated reference module receiver. A first pulse generator is coupled to the calibrated reference module. A second pulse generator is coupled to the production module. A first attenuator is coupled between the calibrated reference module receiver and the production module transmitter. A second attenuator is coupled between the production module receiver and the calibrated reference module transmitter. The calibrated reference module and the production module are optic modules.

### BACKGROUND OF THE INVENTION

1. Field of the Invention

The present invention is generally in the field of fiber-optics. More specifically, the invention is in the field of fiber-optic module calibration.

2. Background Art

Conventional approaches to fiber-optic (or simply optic) module calibration have involved the calibration of parameters such as transmit power, extinction ratio control, and received power over temperature and voltage using specialized test systems. The cost of a single specialized test system can be on the order of tens or hundreds of thousands of dollars.

Referring to FIG. 1, a conventional specialized test system 100 is illustrated. Test station 110 is coupled to personal computer (PC) 112, which serves as a controller. An optic module that is to be calibrated, or module under calibration 114, is plugged, socketed or soldered onto test station 110. Module under calibration 114 comprises reference receiver 116 and transmitter 118. Bit error rate tester (BERT) 120 is coupled to module under calibration 114 via receive line 122 and transmit line 124. BERT is also sometimes referred to as a Bit Error Ratio Tester, which comprises a device which can count either the absolute number or rate of errors or provide that number as a ratio of good to bad bits.

Programmable optic attenuator 126 is coupled between transmitter 118, BERT 120, and PC 112. Programmable optic attenuator 128 is coupled between reference receiver 116 and BERT 120. PC 112 is also coupled to BERT 120 and module under calibration 114 on test station 110. Specialized test system 100 typically includes an oscilloscope 121 and a power meter, among other devices.

In use, in a first step, reference module under calibration 114 is powered up and the transmit power of transmitter 118 is adjusted, via PC 112, to the middle of a target specification range. Typically this range is from about −1 dbm to about −3 dbm (decibels relative to 1 milliwatt). The transmit power is adjusted by adjusting the modulation current and bias current via PC 112, while at the same time keeping the extinction ratio above the target minimum. Typically the target minimum for the extinction ratio is in the range of about 6 to about 8 dB. The extinction ratio is the ratio of the zero level to the one level of the optic signal. These various values are measured by specialized test system 100 and stored as calibrated values.

In a second step, in order to calibrate reference receiver 116 of module under calibration 114, reference receiver 116 is starved of signal until the bit error rate (BER) exceeds a target value. The value of the power received by reference receiver 116 is stored as a calibrated value of input power.

In a third step, the value of received power at reference receiver 116 is measured by module under calibration 114 and compared to the known applied value of power. A correction factor and the received power level are recorded.

In a fourth step, loss-of-signal (LOS) hysteresis are measured and recorded. These four steps are repeated over various voltages and temperatures.

Module under calibration 114 can be calibrated manually, such as by adjusting a potentiometer for example, or automatically. This time-consuming and expensive process is typically repeated for a plurality of modules to be calibrated.

Thus, it is seen that there is need in the art for an improved system and method for calibrating an optic module. The system and method should allow for relatively inexpensive calibration.

### SUMMARY OF THE INVENTION

The present invention is directed to optic module calibration. The invention overcomes the need in the art for an improved system and method for calibrating an optic module and allows for relatively inexpensive calibration.

According to one embodiment of the invention, a system is provided for calibrating a production module having a production module transmitter and a production module receiver. A calibrated reference module includes a calibrated reference module transmitter and a calibrated reference module receiver. A first pulse generator is coupled to the calibrated reference module. A second pulse generator is coupled to the production module. A first attenuator is coupled between the calibrated reference module receiver and the production module transmitter. A second attenuator is coupled between the production module receiver and the calibrated reference module transmitter. The calibrated reference module and the production module are optic modules.

According to another embodiment of the invention, a system is provided for calibrating a production module having a production module transmitter and a production module receiver. A calibrated reference module includes a calibrated reference module transmitter and a calibrated reference module receiver. A first attenuator is coupled between the calibrated reference module receiver and the production module transmitter. A second attenuator is coupled between the production module receiver and the calibrated reference module transmitter. The calibrated reference module and the production module are optic modules.

According to another embodiment, a reference module is calibrated using specialized test equipment. A production module is coupled to the calibrated reference module. A transmit power level of the production module transmitter is adjusted to a first target value while maintaining an extinction ratio above a target minimum. A signal to the production module receiver is attenuated until a bit error rate of the production module exceeds a second target value. A received power level of the production module is compared to an applied power level. The production module is thus calibrated with respect to the calibrated reference module.

Other features and advantages of the present invention will become more readily apparent to those of ordinary skill in the art after reviewing the following detailed description and accompanying drawings.

### BRIEF DESCRIPTION OF THE DRAWINGS

FIG. 1 illustrates a conventional system for calibrating an optic module.

FIG. 2 illustrates a method for calibrating an optic module according to one embodiment of the invention.

FIG. 3A illustrates a system for calibrating an optic module according to one embodiment of the invention.

FIG. 3B illustrates a system for calibrating an optic module according to another embodiment of the invention.

### DETAILED DESCRIPTION OF THE INVENTION

The present invention is directed to optic module calibration. Although the invention is described with respect to specific embodiments, the principles of the invention, as defined by the claims appended herein, can obviously be applied beyond the specifically described embodiments of the invention described herein. Moreover, in the description of the present invention, certain details have been left out in order to not obscure the inventive aspects of the invention. The details left out are within the knowledge of a person of ordinary skill in the art.

The drawings in the present application and their accompanying detailed description are directed to merely example embodiments of the invention. To maintain brevity, other embodiments of the invention which use the principles of the present invention are not specifically described in the present application and are not specifically illustrated by the present drawings.

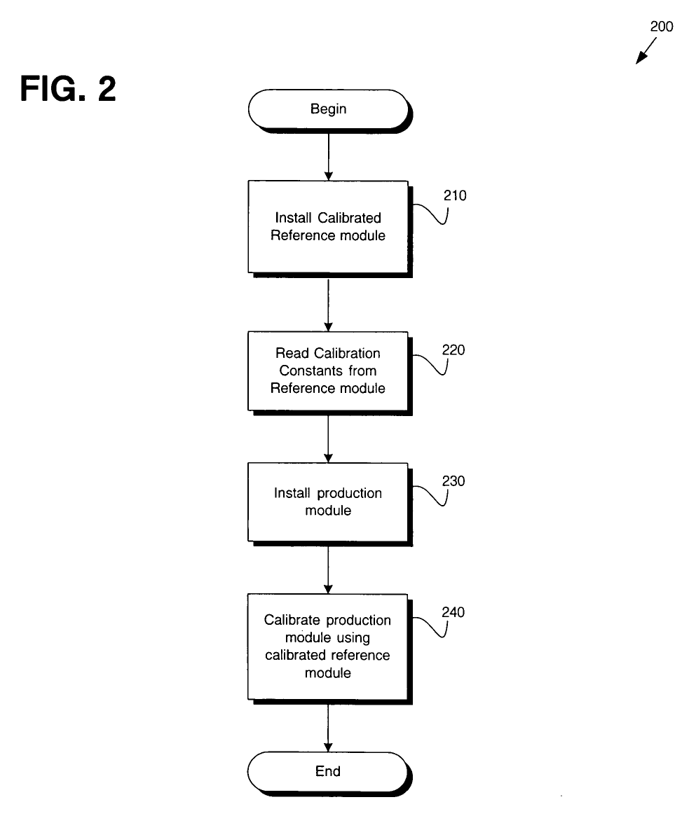

FIG. 2 shows flowchart 200 that describes the steps, according to one embodiment of the invention, in calibrating a production module. Certain details and features have been left out of flowchart 200 that are apparent to a person of ordinary skill in the art. For example, a step may consist of one or more substeps or may involve specialized equipment, as is known in the art. While steps 210 through 240 indicated in flowchart 200 are sufficient to describe one embodiment of the present invention, other embodiments of the invention may use steps different from those shown in flowchart 200.

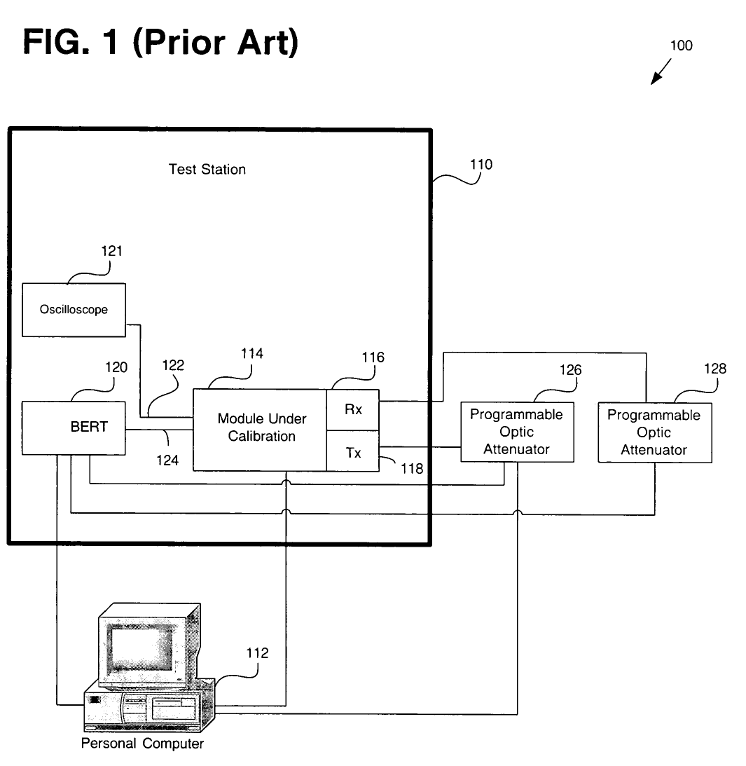

At step 210, a calibrated reference module is installed on a test board. This module corresponds to module under calibration 114 of FIG. 1.

In one embodiment, the calibration of the reference module can be performed in a manner similar to the calibration of module under calibration 114 discussed with reference to FIG. 1. Typically, very expensive test equipment is used to calibrate the module and produce a calibrated reference module, which is referred to as a golden module for purposes of this application.

At step 220, calibration constants are read from the calibrated reference module, and at step 230, a production module is installed on a reference board on which the calibrated reference module (golden module) is installed. Once a golden module has been obtained, modules (which are referred to as silver modules for purposes of this application) can be achieved by calibrating production modules with respect to the single golden module without the use of specialized test equipment.

At step 240, the production module is calibrated using the calibrated reference module or the golden module, thus producing a silver module. Advantageously, expensive specialized test equipment does not need to be used once the calibrated reference module or the golden module is obtained. Thus, a large number of production modules can be calibrated from a single calibrated reference module.

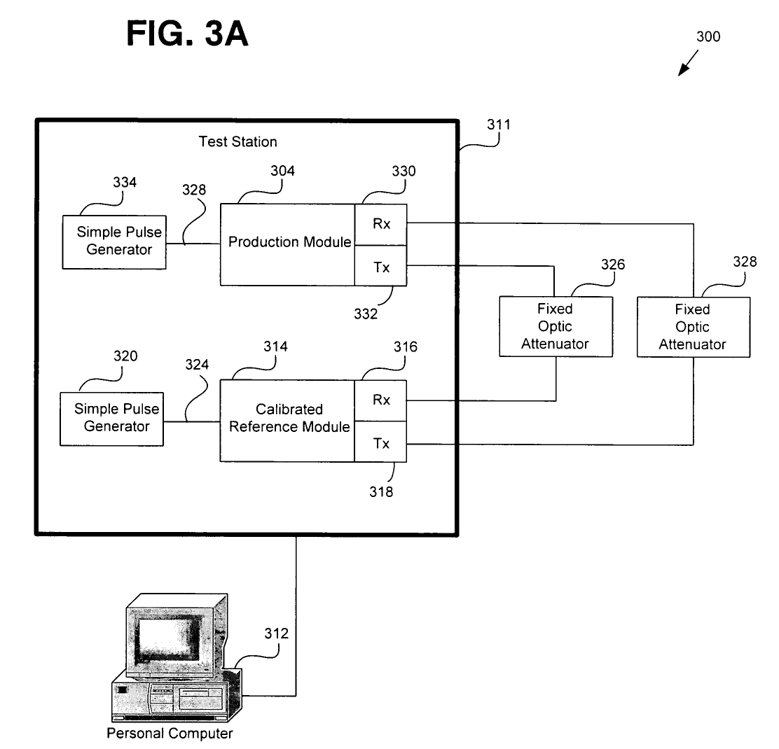

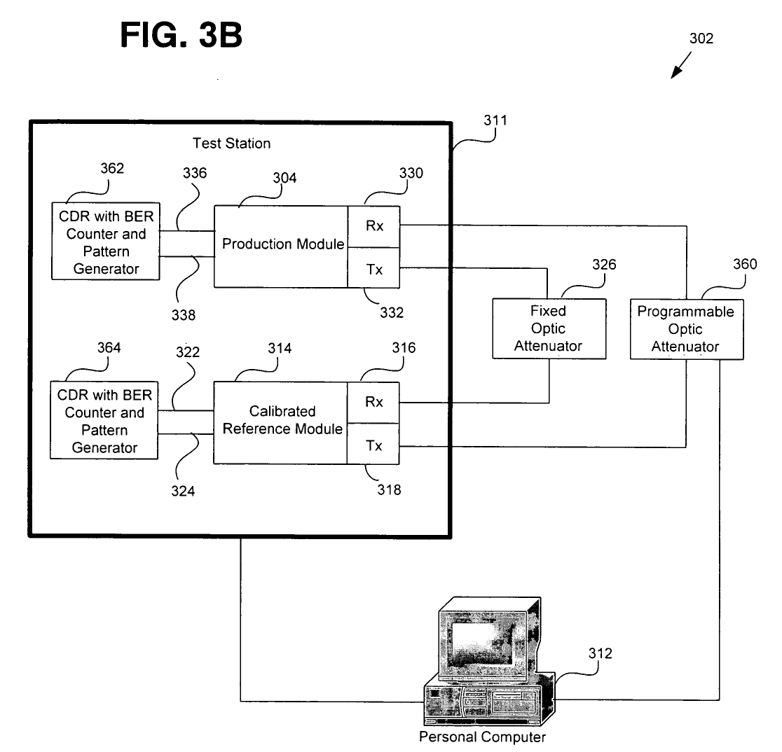

Referring to FIG. 3A, system 300 for calibrating an optic module, or production module 304, according to one embodiment of the invention is illustrated. It should be borne in mind that, unless noted otherwise, like or corresponding elements among FIGS. 1, 3A, and 3B are indicated by like or corresponding reference numerals.

Calibrated reference module 314 is plugged into test station 311. Calibrated reference module 314 comprises receiver 316 and transmitter 318. Calibrated reference module 314 is coupled to simple pulse generator 320, which is also on test station 311. Simple pulse generator 320 is coupled to calibrated reference module 314 via transmit line 324. Calibrated reference module 314 and production module 304 both include an integrated controller and a laser driver in one embodiment.

Production module 304 is plugged into test station 311. Production module 304 comprises receiver 330 and transmitter 332. Production module 304 is coupled to simple pulse generator 334, which is also on test station 311. Simple pulse generator 334 is coupled to production module 304 via transmit line 328. It is envisioned that simple pulse generators 320 and 334 can be replaced with a single pulse generator having one output driving calibrated reference module 314 and another output driving production module 304.

Fixed optic attenuator 326 is coupled between receiver 316 of calibrated reference module 314 and transmitter 332 of production module 304. Fixed optic attenuator 328 is coupled between receiver 330 of production module 304 and transmitter 318 of calibrated reference module 314. It is noted that fixed optic attenuator 326 can be replaced with a programmable optic attenuator. PC 312 is coupled to production module 304 and calibrated reference module 314. PC 312 can also be coupled to simple pulse generators 320 and 334.

In use, calibrated reference module 314 is instructed, via PC 312, to transmit a known optic power that has a known extinction ratio from transmitter 318 of calibrated reference module 314. A laser bias current is set to achieve the desired output power, as measured by calibrated reference module 314. Fixed optic attenuators 326 and 328 can be switched in to provide some loss. Fixed optic attenuators 326 and 328 can each comprise a length of optic fiber (e.g. 10, 20, or 80 kilometers in length) in one illustrative embodiment. Fixed optic attenuators 326 and 328 help duplicate the real effects of optic fiber over long distances, introducing delays and phase shifts.

After the signal from transmitter 318 gets attenuated by fixed optic attenuator 328, the signal is received by receiver 330 of production module 304. A mapping is performed of the laser's power/current characteristics. The extinction ratio and the power level of the transient signal from transmitter 318 can be determined by interrogating calibrated reference module 314. Thus, from this extinction ratio, and the link loss between calibrated reference module 314 and production module 304, it can be determined what the received power should be at receiver 330.

Subsequently, production module 304 is interrogated to determine that production module 304 measures the received power from receiver 330, and a correction is applied for any discrepancy. Using the results of the laser mapping, modulation and bias currents are set to achieve a desired extinction ratio. The transmit power level is calibrated based on the optic power measurement at calibrated reference module 314. The receive power level is calibrated from the signal provided by calibrated reference module 314. Various warnings, alarm levels, and registers are then loaded in a memory of production module 304 for reference during actual usage.

Referring to FIG. 3B, system 302 for calibrating an optic module, or production module 304, according to another embodiment of the invention is illustrated. Calibrated reference module 314 is plugged into test station 311. Calibrated reference module 314 comprises receiver 316 and transmitter 318. Calibrated reference module 314 is coupled to clock and data recovery circuit (CDR) with BER counter and pattern generator 364, which is also on test station 311. CDR with BER counter and pattern generator 364 is coupled to calibrated reference module 314 via receive line 322 and transmit line 324.

Production module 304 is plugged into test station 311. Production module 304 comprises receiver 330 and transmitter 332. Production module 304 is coupled to CDR with BER counter and pattern generator 362, which is also on test station 311. CDR with BER counter and pattern generator 362 is coupled to production module 304 via receive line 336 and transmit line 338. CDR with BER counter and pattern generators 362 and 364 generally can represent any suitable set of integrated circuits (ICs) that can be used to generate test signals and to measure the quality of the return signal (e.g. jitter and other parameters), in one embodiment. As is known in the art, a pattern generator simply generates a test signal, and a BER counter is a device that measures the BER.

In keeping with some embodiments of the invention, fixed optic attenuator 326 is coupled between transmitter 332 of production module 304 and receiver 316 of calibrated reference module 314. Programmable optic attenuator 360 is coupled between receiver 330 of production module 304 and transmitter 318 of calibrated reference module 314. PC 312 is coupled to production module 304 and calibrated reference module 314. PC 312 can also be coupled to CDR with BER counter and pattern generators 362 and 364.

In use, a laser driver configuration, desired optic output power, and extinction ratio are downloaded into production module 304. The laser bias current is set to achieve the desired output power, as measured at receiver 316 of calibrated reference module 314. A mapping of the laser's power/current characteristics is performed.

Using the results of the mapping, the modulation current is set to achieve a desired extinction ratio. The transmit power level is calibrated based on the optic power measurement from calibrated reference module 314. The receive power level of production module 304 is calibrated based on the optic power level from calibrated reference module 314, and various warnings, alarm levels, and registers are then loaded. It is noteworthy that additional attenuation can be introduced, either automatically using programmable optic attenuator 360 or manually, until production module 304 is starved of signal to the point where the sensitivity threshold for a given BER can be determined.

When calibrating transmitter 332 of production module 304, transmitter 332 is instructed to output a transmit signal. Receiver 316 of calibrated reference module 314 is used to measure the transmitted power from transmitter 332 of production module 304 in addition to the extinction ratio. In some cases, little or no attenuation may be required. However, some attenuation may be introduced, via fixed optic attenuator 326 for example, to ensure that receiver 316 of calibrated reference module 314 is not damaged.

One advantage of the present system is that calibrated reference module 314 can be used as a specification with respect to which a plurality of other optic modules are calibrated. Once module under calibration 314 has been calibrated to achieve calibrated reference module 314, expensive specialized test equipment need no longer be used. Advantageously, calibration of large volumes of optic modules can thus be achieved at a relatively low cost. Conventional implementations required repeated use of expensive specialized test equipment and did not allow for a single optic module to be a reference for subsequently calibrating a plurality of other optic modules.

Another advantage of the present invention is that production module 304 and calibrated reference module 314 each include a microprocessor-based controller and state machine in one embodiment. Alternative embodiments may contain only a state machine, microcontroller (microprocessor) or both. The controller and or state machine can be configured to default to various modes as needed (e.g. a calibration and setup mode, a reference module mode, etc.). In one embodiment, the microprocessor(s) and/or state machine may comprise a Digital Diagnostic Monitoring Interface (DDMI) chip and run special firmware that places production module 304 into a reference mode, for example. The DDMI chip(s) allow PC 312 to control production module 304 and calibrated reference module 314, and to set various values for the optic modules.

An additional advantage is that the present system can use external ICs in order to achieve reduced cost. The external ICs generate test patterns at different bit rates and receive patterns, in lieu of using expensive specialized test equipment. The external ICs also measure the received electrical performance (e.g. BER, rise/fall time, jitter, and the like).

It is noteworthy that module-to-module communication in the present system can be performed via an external loop-back connection in addition to the fiber-optic connections. Alternatively, a fiber-optic data signaling link can be used alone as described in U.S. patent application titled “Module to Module Signaling Utilizing Amplitude Modulation”, filed Aug. 10, 2004, having Ser. No. 10/916,216, assigned to the assignee of the present application, which is hereby fully incorporated by reference. Thus calibration can be performed with a minimum of connections. In one embodiment, intra-system communication is performed via an I²C interface.

An additional benefit achieved by the present system involves changing the transmit parameters over time to compensate for the degradation of optic components such as lasers after a module containing such an enabled device with associated firmware has been placed into service. Conventional approaches do not accomplish the foregoing without the help of a host system or supervisory controller. Conventional systems do not allow modules to communicate with each other, and did not optimize optic link performance without the intervention of a supervisory device or system.

Therefore, another advantage achieved includes providing the ability to change the operating characteristics of the optic modules in the field remotely, without local intervention. In devices enabled with the necessary hardware and firmware, the need for a separate supervisory system to perform the foregoing duty is not mandated, allowing implementation in relatively low-cost links. The present system further allows for simpler and quicker troubleshooting than conventional methods, and is less error prone.

From the above description of the invention it is manifest that various techniques can be used for implementing the concepts of the present invention without departing from its scope. Moreover, while the invention has been described with specific reference to certain embodiments, a person of ordinary skill in the art would recognize that changes can be made in form and detail without departing from the spirit and the scope of the invention. The described embodiments are to be considered in all respects as illustrative and not restrictive. It should also be understood that the invention is not limited to the particular embodiments described herein, but is capable of many rearrangements, modifications, and substitutions without departing from the scope of the invention. For example, although the systems and methods have been described with respect to optic modules and optic attenuators, it is contemplated that other types of modules and attenuators might be used in conjunction with embodiments according to the present invention.

Thus optic module calibration has been described.

1. A system for calibrating a production module having a production module transmitter and a production module receiver, the system comprising:
a calibrated reference module having a calibrated reference module transmitter and a calibrated reference module receiver;
a first pulse generator coupled to said calibrated reference module;
a second pulse generator coupled to said production module;
a first attenuator coupled between said calibrated reference module receiver and said production module transmitter;
a second attenuator coupled between said production module receiver and said calibrated reference module transmitter.

2. The system of claim 1 wherein said first pulse generator is a simple pulse generator.

3. The system of claim 1 wherein said first pulse generator and said second pulse generator are the same pulse generator.

4. The system of claim 1 wherein said first attenuator is a fixed optic attenuator.

5. The system of claim 1 wherein said second attenuator is a fixed optic attenuator.

6. The system of claim 1 wherein said calibrated reference module is an optic module.

7. The system of claim 1 wherein said production module is an optic module.

8. The system of claim 1, further comprising a personal computer coupled to said calibrated reference module and said production module.

9. A system for calibrating a production module having a production module transmitter and a production module receiver, the system comprising:
a calibrated reference module having a calibrated reference module transmitter and a calibrated reference module receiver;
a first bit error rate tester coupled to said calibrated reference module;
a second bit error rate tester coupled to said production module;
a first attenuator coupled between said calibrated reference module receiver and said production module transmitter;
a second attenuator coupled between said production module receiver and said calibrated reference module transmitter.

10. The system of claim 9 wherein said first attenuator is a fixed optic attenuator.

11. The system of claim 9 wherein said first attenuator is a programmable optic attenuator.

12. The system of claim 9 wherein said second attenuator is a fixed optic attenuator.

13. The system of claim 9 wherein said first bit error rate tester is a first CDR with BER counter and pattern generator.

14. The system of claim 9 wherein said second bit error rate tester is a second CDR with BER counter and pattern generator.

15. The system of claim 9 wherein said calibrated reference module is an optic module.

16. The system of claim 9 wherein said production module is an optic module.

17. The system of claim 9, further comprising a personal computer coupled to said calibrated reference module, said production module, and said second attenuator.

18. A method of calibrating a production module, the method comprising:
calibrating a reference module using specialized test equipment;
coupling said production module to said calibrated reference module;
adjusting a transmit power level of said production module transmitter to a first target value while maintaining an extinction ratio above a target minimum;
attenuating a signal to said production module receiver until a bit error rate of said production module exceeds a second target value;
comparing a received power level of said production module to an applied power level.

19. The method of claim 18 wherein said production module is an optic module.

20. The method of claim 18 wherein said calibrated reference module is an optic module.
